(19) United States
(12) Patent Application Publication
(10) Pub. No.: US 2026/0123105 A1
(43) Pub. Date: Apr. 30, 2026

(54) HIGH-RELIABILITY MICRO LIGHT-EMITTING DIODE AND METHOD FOR MANUFACTURING THE SAME

(71) Applicant: Korea Institute of Energy Technology, Naju-si (KR)

(72) Inventors: Joon Seop KWAK, Suncheon-si (KR); Tae Kyoung KIM, Osan-si (KR)

(21) Appl. No.: 19/079,491

(22) Filed: Mar. 14, 2025

(30) Foreign Application Priority Data
Oct. 29, 2024 (KR) 10-2024-0149466

(51) Int. Cl. H10H 20/815; H10H 20/821; H10H 20/857

(52) U.S. Cl. CPC H10H 20/815; H10H 20/821; H10H 20/857

(57) ABSTRACT

A micro-LED includes: a substrate, a first semiconductor layer laminated on an upper surface of the substrate, a first electrode pad formed on an upper surface of the first semiconductor layer, an active layer laminated on an upper surface of the first semiconductor layer, a second semiconductor layer laminated on an upper surface of the active layer, a second electrode pad formed on the second semiconductor layer, and a stress recovery passivation layer configured to recover stress relaxation of the active layer caused by etching, the stress recovery passivation layer comprising a first passivation layer deposited by particles having a first energy on a portion of the upper surface and sidewalls of a mesa structure, where the mesa structure includes the active layer and the second semiconductor layer laminated together by etching.

### CROSS-REFERENCE TO RELATED APPLICATION

This application claims priority from and the benefit of Korean Patent Application No. 10-2024-0149466 filed on Oct. 29, 2024, in the Korean Intellectual Property Office, the disclosure of which is incorporated herein by reference.

### BACKGROUND OF THE DISCLOSURE

### Field of the Disclosure

Example embodiments relate to a micro light-emitting diode, and more specifically, to a micro light-emitting diode with high-reliability characteristics achieved by controlling the stress on the mesa-etched sidewalls or through lattice recrystallization, and a method for manufacturing the same.

### Description of the Related Art

The biggest issue with micro light-emitting diodes (micro-LEDs) is that as their size decreases, light output diminishes, leading to a sharp decline in external quantum efficiency and a significant deterioration in reliability. These problems associated with the miniaturization of micro-LEDs are reported to primarily stem from dry etching damage during the mesa etching or isotropic etching processes. Specifically, it has been discovered very recently that the root cause is strain relaxation occurring during the mesa etching or isotropic etching processes.

### SUMMARY

An objective of example embodiments is to provide a micro light-emitting diode (micro-LED) with high-reliability characteristics and a method for manufacturing the same, by applying a method to minimize or recover dry etching damage during mesa etching or isotropic etching processes.

Another objective of example embodiments is to provide a micro-LED with high-reliability characteristics and a method for manufacturing the same, wherein dry etching damage during the mesa etching or isotropic etching processes is minimized by resolving lattice defects on the etched sidewalls or controlling strain relaxation in the active layer, specifically in the MQWs (multi-quantum wells), through the deposition of a passivation layer using high-energy plasma in the mesa etching region.

According to an example embodiment, a micro-LED may comprise: a substrate, a first semiconductor layer laminated on an upper surface of the substrate, a first electrode pad formed on an upper surface of the first semiconductor layer, an active layer laminated on an upper surface of the first semiconductor layer, a second semiconductor layer laminated on an upper surface of the active layer, a second electrode pad formed on the second semiconductor layer, and a stress recovery passivation layer configured to recover stress relaxation of the active layer caused by etching, the stress recovery passivation layer comprising a first passivation layer deposited by particles having a first energy on a portion of the upper surface and sidewalls of a mesa structure, wherein the mesa structure comprises the active layer and the second semiconductor layer laminated together by etching.

According to an example embodiment, the insulating material forming the stress recovery passivation layer may include at least one of SiO₂, SixNy, SiOxNy, AlN, AlxOy, ZnO, MgO, NiO, SnxOy, GaxOy, InxOy, ytrria-stabilized zirconia (YSZ), or GaOxNy.

According to an example embodiment, the particles having the first energy may be particles with an energy of 50 W to 3000 W, generated by at least one of DC plasma, pulsed DC plasma, RF plasma, LF plasma, DC-RF plasma, ion beam irradiation, or electron beam irradiation.

According to an example embodiment, the stress recovery passivation layer may further comprise a second passivation layer deposited on the upper surface of the first passivation layer by particles having a second energy.

According to an example embodiment, the particles having the second energy may be particles with an energy of 50 W to 3000 W, generated by at least one of DC plasma, pulsed DC plasma, RF plasma, LF plasma, DC-RF plasma, ion beam irradiation, or electron beam irradiation.

According to an example embodiment, the stress recovery passivation layer may further comprise a third passivation layer deposited on the sidewalls of the mesa structure beneath the first passivation layer by particles having the first energy, the third passivation layer being configured to recover stress relaxation of the active layer caused by etching.

According to an example embodiment, the micro-LED may comprise: a substrate, a first semiconductor layer laminated on an upper surface of the substrate, a first electrode pad formed on an upper surface of the first semiconductor layer, an active layer laminated on an upper surface of the first semiconductor layer, a second semiconductor layer laminated on an upper surface of the active layer, a second electrode pad formed on the second semiconductor layer, and a mesa structure formed by etching the second semiconductor layer, wherein the mesa structure has a shape of at least a polygon with five or more sides or a circular shape.

According to an example embodiment, the micro-LED may comprise: a substrate, a first semiconductor layer laminated on an upper surface of the substrate, a first electrode pad formed on an upper surface of the first semiconductor layer, an active layer laminated on an upper surface of the first semiconductor layer, a second semiconductor layer laminated on an upper surface of the active layer, a second electrode pad formed on the second semiconductor layer, and a passivation layer formed on a portion of the upper surface and sidewalls of an inverted mesa structure, where the active layer and the second semiconductor layer are laminated, and on a portion of the exposed upper surface of the first semiconductor layer, wherein the inverted mesa structure is formed by etching the second semiconductor layer, and its sidewalls have a downward slope of 80 degrees to 130 degrees relative to its upper surface.

According to an example embodiment, another aspect of the invention provides a method for manufacturing a micro-LED, comprising: growing a first semiconductor layer, an active layer, and a second semiconductor layer sequentially on an upper surface of a substrate, forming a mesa structure comprising the first semiconductor layer, the active layer, and the second semiconductor layer by etching, and forming a stress recovery passivation layer on a portion of the upper surface and sidewalls of the mesa structure, and on a portion of the exposed upper surface of the first semiconductor layer by applying a mask with patterns for a first electrode pad and a second electrode pad, wherein forming the stress recovery passivation layer comprises depositing a first passivation layer on a portion of the upper surface and sidewalls of the mesa structure by particles having a first energy to recover stress relaxation of the active layer caused by etching.

According to an example embodiment, the particles having the first energy used in forming the stress recovery passivation layer may be particles with an energy of 50 W to 3000 W, generated by at least one of DC plasma, pulsed DC plasma, RF plasma, LF plasma, DC-RF plasma, ion beam irradiation, or electron beam irradiation.

According to an example embodiment, forming the stress recovery passivation layer may further comprise forming a second passivation layer on the upper surface of the first passivation layer by particles having an energy of 50 W to 3000 W after depositing the first passivation layer.

According to an example embodiment, forming the stress recovery passivation layer may further comprise, before forming the first passivation layer, depositing a third passivation layer on the sidewalls of the mesa structure by particles having the first energy to recover stress relaxation of the active layer caused by etching.

According to an example embodiment, dry etching damage during mesa etching or isotropic etching processes may be minimized or recovered to significantly enhance the EQE (External Quantum Efficiency) effect, thereby providing a micro light-emitting diode (micro-LED) with high-reliability characteristics.

According to an example embodiment, lattice defects on the etched sidewalls may be resolved or strain relaxation in the active layer, specifically in MQWs (multi-quantum wells), may be controlled by depositing a passivation layer using high-energy plasma in the mesa etching region. This minimizes dry etching damage during mesa etching or isotropic etching processes, significantly improves EQE, and thus provides a micro-LED with high-reliability characteristics.

The effects of the present invention are not limited to those mentioned above, and other effects not explicitly stated may be clearly understood by those skilled in the art from the description below.

### BRIEF DESCRIPTION OF THE FIGURES

Embodiments will be described in more detail with regard to the figures, wherein like reference numerals refer to like parts throughout the various figures unless otherwise specified, and wherein:

FIG. 1 is a diagram illustrating micro-Raman mapping of the active region after performing mesa etching on a micro-LED with a size of 60×60 μm².

FIG. 2 is a diagram illustrating micro-Raman mapping of the active region after performing mesa etching on a micro-LED with a size of 40×40 μm².

FIG. 3 is a graph illustrating changes in EQE (External Quantum Efficiency) according to the size reduction of the micro-LED.

FIG. 4 is a graph showing the STEM images and X-ray diffraction analysis results of the active layer and passivation layer (SiO₂) deposited using PECVD and sputtering according to the present invention after mesa etching.

FIG. 5 is a partial cross-sectional view of the micro-LED according to the first embodiment of the present invention.

FIG. 6 is a process diagram illustrating a method for manufacturing a micro-LED to compensate for strain relaxation in the mesa region according to the first embodiment of the present invention.

FIG. 7 is a partial cross-sectional view of the micro-LED according to the second embodiment of the present invention.

FIG. 8 is a process diagram illustrating a method for manufacturing a micro-LED to compensate for strain relaxation in the mesa region according to the second embodiment of the present invention.

FIG. 9 is a partial cross-sectional view of the micro-LED according to the third embodiment of the present invention.

FIG. 10 is a process diagram illustrating a method for manufacturing a micro-LED to compensate for strain relaxation in the mesa region according to the third embodiment of the present invention.

FIG. 11 is a plan view of the strain relaxation-preventing mesa structure according to an embodiment of the present invention.

FIGS. 12A to 12C are a partial cross-sectional view of a micro-LED having a strain relaxation-preventing inverted mesa structure according to an embodiment of the present invention.

FIG. 13 is a plan view of the strain relaxation-preventing inverted mesa structure according to an embodiment of the present invention.

FIGS. 14A to 14C are a partial cross-sectional view and TEM image of the micro-LED before and after passivation layer deposition following mesa etching.

FIGS. 15A to 15D are a graph illustrating the electrical characteristics of a micro-LED fabricated using the high-energy plasma power deposition method.

FIGS. 16A to 16C are a graph illustrating the external quantum efficiency (EQE) characteristics of a micro-LED fabricated using the high-energy plasma power deposition method.

FIGS. 17A to 17D are a graph illustrating the external quantum efficiency (EQE) characteristics of a micro-LED fabricated using the high-energy plasma power deposition method.

### DETAILED DESCRIPTION OF THE DISCLOSURE

The terms used in this specification are intended to describe example embodiments and are not intended to limit the present invention. In this specification, the singular forms are intended to include the plural forms as well, unless explicitly stated otherwise or context clearly dictates otherwise.

The terms “comprises” and/or “comprising” used in this specification do not exclude the presence or addition of one or more other components or steps besides the elements or steps explicitly mentioned.

Terms such as “embodiment,” “example,” “aspect,” and “illustration” used in this specification are not to be interpreted as indicating that any particular aspect or design is superior or advantageous compared to others.

Furthermore, the term “or” is intended to mean “inclusive or” rather than “exclusive or,” unless explicitly stated otherwise or clearly indicated by context. For example, the expression “x uses a or b” should be interpreted to include any natural inclusive permutations unless otherwise specified.

Additionally, the singular expressions “a” or “an” used in this specification and the claims should generally be interpreted as meaning “one or more” unless explicitly stated otherwise or clearly indicated by context to refer to the singular form.

The terms used in the following description are selected to be general and universal in the related technical field, but other terms may exist due to advancements, changes, conventions, or user preferences in the technology. Therefore, the terms used in the following description should not be understood to limit the technical idea but should be regarded as illustrative terms to describe the embodiments.

In some cases, specific terms may be arbitrarily selected by the applicant, and in such cases, their meanings will be described in detail in the relevant parts of the description. Therefore, the terms used in the following description should be understood based on their meanings and the overall context of this specification, not simply by their names.

Unless otherwise defined, all terms (including technical and scientific terms) used in this specification may be interpreted as having meanings commonly understood by those skilled in the art to which the present invention pertains. Terms generally defined in dictionaries should not be overly or ideally interpreted unless explicitly defined otherwise. Meanwhile, in describing the present invention, detailed descriptions of related known functions or configurations may be omitted if it is determined that such descriptions would unnecessarily obscure the gist of the present invention.

The terminology used in this specification is intended to adequately describe the embodiments of the present invention and may vary depending on user or operator intent or conventions in the relevant field. Accordingly, definitions of these terms should be made based on the entire content of this specification.

Hereinafter, the embodiments of the present invention will be described in detail with reference to the accompanying drawings and the descriptions provided therein. However, the present invention is not limited or restricted by the embodiments.

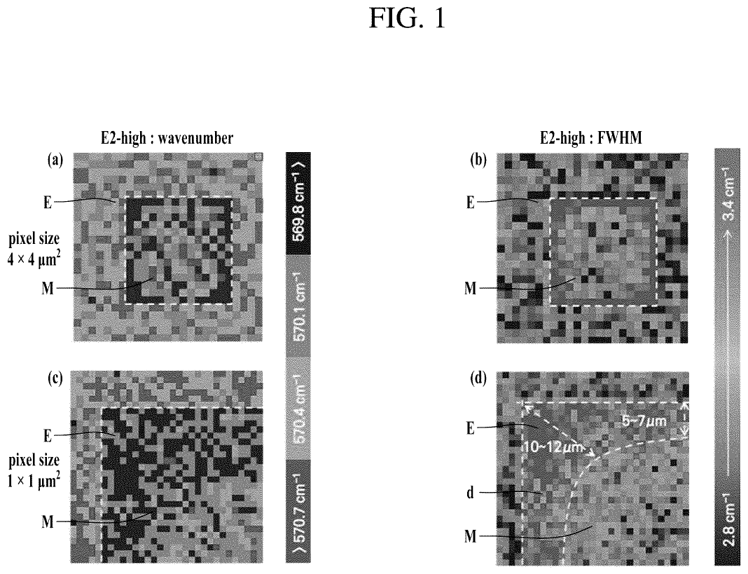

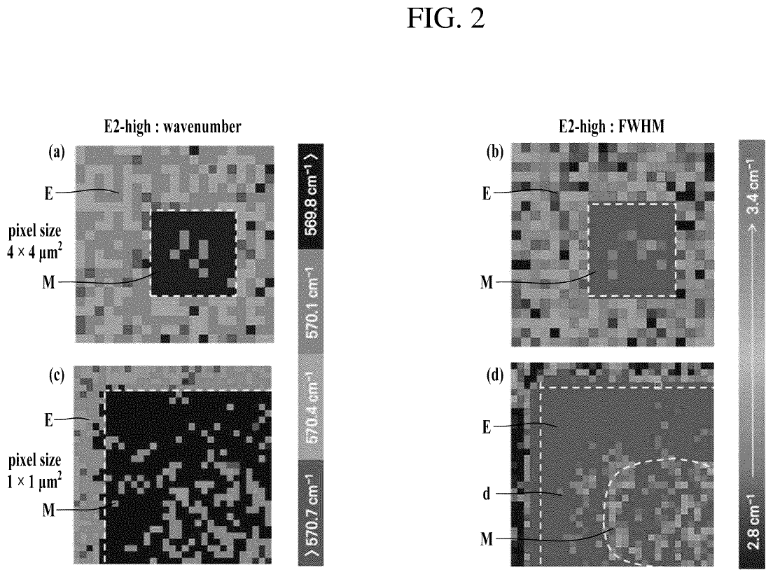

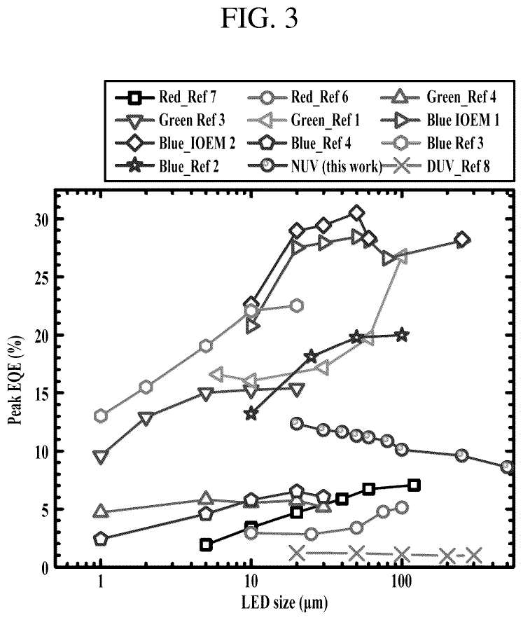

FIG. 1 illustrates micro-Raman mapping of the active layer after performing mesa etching on a micro-LED with a size of 60×60 μm², and FIG. 2 illustrates micro-Raman mapping of the mesa structure (M) after performing mesa etching on a micro-LED with a size of 40×40 μm². FIG. 3 is a graph illustrating changes in EQE (External Quantum Efficiency) corresponding to the size reduction of the micro-LED.

As shown in FIGS. 1 and 2, the crystalline structure in the mesa etching region (E) may be damaged due to dry mesa etching or ISO dry etching processes during the manufacture of micro-LEDs. Consequently, the mesa structure (M) formed after mesa etching or dry etching exhibits stress relaxation in the crystalline structure of the material constituting the internal active layer (MQW). This stress relaxation occurring within the crystalline structure of the mesa structure (M) is a primary cause of the sharp decline in EQE observed in micro-LEDs with sizes of 40×40 μm² or smaller, as shown in FIG. 3.

FIG. 1 presents micro-Raman mapping of the active layer of a micro-LED after mesa etching. The analyzed micro-LED has a size of 60×60 μm², and the mapping illustrates the distribution of strain and stress relaxation within the mesa structure (M) and the surrounding etched region (E). Variations in wavenumber and full width at half maximum (FWHM) are observed, indicating that strain relaxation occurs predominantly at the mesa edges, affecting the crystal quality of the active layer.

FIG. 2 displays micro-Raman mapping of a 40×40 μm² micro-LED after mesa etching, similar to FIG. 1 but for a smaller device size. The strain distribution within the mesa structure (M) is more pronounced due to the reduced device dimensions, leading to greater relaxation effects in the etched region (E). The mapping also highlights stress concentrations along the mesa boundaries, which can impact the overall performance and efficiency of the micro-LED.

These figures illustrate how the micro-LED's mesa structure and size influence strain relaxation, which plays a critical role in device reliability and optical performance.

The present invention provides a method for recovering or preventing damage caused by stress relaxation in the crystalline structure of the active layer due to dry etching during mesa etching or ISO processes in the manufacture of micro-LEDs.

Specifically, the present invention provides a method for recovering stress relaxation by recrystallizing the damaged crystalline structure of the active layer. This is achieved by forming a mesa structure via dry etching and subsequently depositing a passivation layer on the mesa structure using high-energy particles from DC, RF, pulsed DC plasma, RF plasma, LF plasma, DC-RF plasma, ion beam irradiation, or electron beam irradiation as the first energy source.

The present invention further provides a method for minimizing stress relaxation caused by damage to the crystalline structure of the active layer during etching. This is achieved by replacing the ICP (Inductively Coupled Plasma) etching process, which introduces Cl₂, BCl₃, or Ar₂ plasma during dry etching, with electron beam etching or neutron beam-electron beam etching.

Additionally, the present invention provides a method for minimizing stress relaxation caused by damage to the crystalline structure at the vertices of the mesa structure. This is achieved by forming the planar shape of the mesa structure as a polygon with five or more sides or as a circular shape.

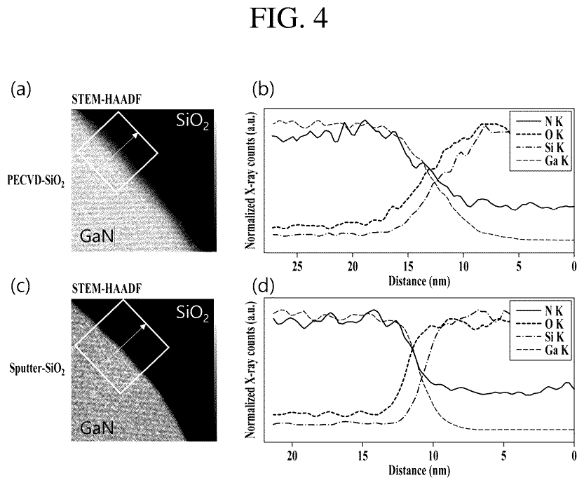

FIG. 4 is a graph illustrating the STEM images and X-ray diffraction analysis results of the active layer and passivation layer (SiO2) deposited using PECVD and sputtering according to the present invention after mesa etching.

(a) and (b) of FIG. 4 show the STEM image and X-ray diffraction analysis results of a mesa structure with an SiO2 passivation layer deposited using low-energy plasma power PECVD at 50 W, respectively. (c) and (d) of FIG. 4 illustrate the STEM image and X-ray diffraction analysis results of a mesa structure with an SiO2 passivation layer deposited using high-energy plasma power sputtering at 250 W.

As shown in (a) of FIG. 4, the SiO2 passivation layer deposited on the mesa structure using low-energy plasma power revealed a non-uniform boundary between the active layer and the passivation layer. Additionally, as depicted in (b) of FIG. 4, the X-ray diffraction analysis results showed that the boundary between the active layer and the passivation layer was unclear, indicating diffusion between the two layers leading to an indistinct boundary.

In contrast, as shown in (c) of FIG. 4, the SiO₂ passivation layer deposited on the mesa structure using high-energy plasma power revealed a uniform boundary between the active layer and the passivation layer. Furthermore, as depicted in (d) of FIG. 4, the X-ray diffraction analysis results confirmed that the boundary between the active layer and the passivation layer was distinctly separated, with minimized diffusion between the layers.

In summary, applying low-energy plasma power, the second energy, to the mesa structure did not recover stress relaxation in the crystalline structure of the active layer caused by dry etching. However, applying high-energy plasma power, the first energy, enabled the recovery of stress relaxation in the active layer.

As described above, after performing mesa etching, ion beam irradiation or electron beam irradiation can be applied to the mesa structure to impart impact to the crystalline structure with high-energy particles, enabling stress relaxation recovery.

Preferably, the first energy of high-energy plasma particles and the second energy of low-energy plasma particles generated by at least one of DC plasma, pulsed DC plasma, RF plasma, LF plasma, DC-RF plasma, ICP plasma, ion beam irradiation, or electron beam irradiation can range from 50 W to 3000 W. The first energy can be higher than the second energy.

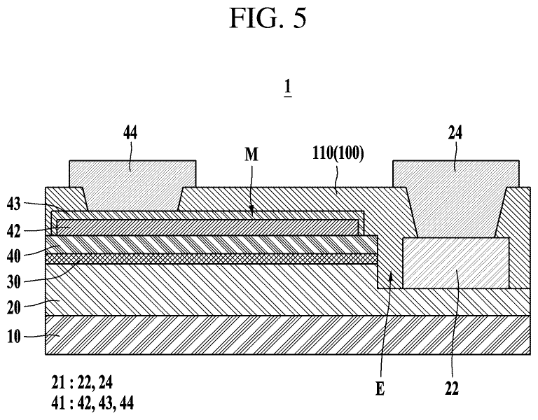

FIG. 5 is a partial cross-sectional view of the micro-LED 1 according to the first embodiment of the present invention.

As shown in FIG. 5, the micro-LED 1 of the first embodiment may comprise: a substrate 10, a first semiconductor layer 20, a first electrode pad 21 formed on the first semiconductor layer 20, an active layer 30, a second semiconductor layer 40, a second electrode pad 41 formed on the second semiconductor layer 40, a mesa structure (M), and a stress recovery passivation layer 100 deposited by high-energy plasma particles on the upper surface of the first semiconductor layer 20 exposed by the dry etching during mesa etching or ISO processes.

The substrate 10 may be made of materials such as sapphire, Si, GaAs, GaN, SiC, or ZnC, but is not limited thereto. A buffer layer (not shown) may also be disposed on the upper surface of the substrate 10.

The buffer layer (not shown) may function as a layer for matching the substrate 10 and the first semiconductor layer 20 by reducing the lattice constant difference between the substrate 10 and the first semiconductor layer 30. The buffer layer may be composed of undoped materials such as GaAs, GaN, AlN, AlGaN, or InGaN, but is not limited thereto.

The first semiconductor layer 20 may be implemented as an n-type semiconductor layer doped with n-type dopants. The first semiconductor layer 20 may include Group III nitrides. The first semiconductor layer 20 may also be an undoped semiconductor layer. The first semiconductor layer 20 may be composed of any one of GaN, InGaN, AlGaN, AlInGaN, GaInP, InP, GaAs, AlGaInP, AlInP, or AlGaAs.

The first semiconductor layer 20 may be formed on the upper surface of the substrate 10 by any one of the methods including epitaxy, chemical vapor deposition (CVD), sputtering, metal-organic chemical vapor deposition (MOCVD), or hydride vapor phase epitaxy (HVPE).

The first electrode pad 21 may be configured to provide electrons to the first semiconductor layer 20 as current is injected. The first electrode pad 21 may include a first ohmic electrode layer 22 and a first bonding electrode layer 24 formed on the first ohmic electrode layer 22.

The first ohmic electrode layer 22 and the first bonding electrode layer 24 may serve as n-type electrodes. The material for the n-type electrode may be at least one metal selected from Cr, ITO, Zr, Mo, Pb, Sn, Au, Ge, Cu, Bi, Cd, Zn, Ag, Ni, Ti, and alloys containing these metals.

The first bonding electrode layer 24 may be deposited as a bonding metal. The bonding metal may be bonded to other electrodes using a eutectic bonding or reflow method, which applies heat and pressure.

The active layer 30 may be a layer that outputs light of a predetermined wavelength as electrons provided from the n-type first semiconductor layer 20 and holes provided from the p-type second semiconductor layer 40 recombine. The active layer 30 may be formed as a multi-layer semiconductor thin film with a multiple quantum well (MQWs) structure, in which well layers and barrier layers are alternately stacked, or with a bulk structure. Since the wavelength of the emitted light varies depending on the semiconductor material constituting the active layer 30, it is desirable to select an appropriate semiconductor material according to the target wavelength.

The active layer 30 may be implemented using materials such as GaN/InGaN, InGaN/InGaN, AlGaN/AlGaN, AlInGaN/InGaN, AlGaN/InGaN, AlGaInP/AlGaInP, AlGaInP/AlInP, AlGaAs/AlGaAs, AlGaAs/GaAs, or AlGaAs/InGaAs.

The second semiconductor layer 40 may be composed of a semiconductor material doped with a p-type dopant. The second semiconductor layer 40 may include one or more of GaN, AlGaN, InGaN, ZnO, AlGaInP, AlInP, AlGaAs, or GaP.

The second electrode pad 41 may include a second ohmic electrode layer 42, a reflective electrode layer 43, and a second bonding electrode layer 44, sequentially stacked. The second ohmic electrode layer 42 may be formed of a single layer, multi-layer, or alloy, including indium tin oxide, zinc oxide, tin oxide, nickel oxide, indium oxide, gallium oxide, aluminum oxide, or oxides containing Al, Ga, Ag, Sn, In, Zn, Co, Ni, or Au with a transmittance of 70% or higher, or metals such as Ni, Au, Mo, Cr, Co, Cu, Rb, Ru, Rh, Pd, Ag, Sn, W, Ir, Pt, La, Ce, Na, or Eu with a thickness of 30 nm or less.

The reflective electrode layer 43 may be formed of Ag, Al, or an alloy containing these materials.

The stress recovery passivation layer 100 may be deposited by high-energy particles on the mesa structure (M) and the upper surface of the first semiconductor layer 20 exposed by mesa etching. The insulating material forming the stress recovery passivation layer 100 may include at least one of SiO₂, SixNy, SiOxNy, AlN, AlxOy, ZnO, MgO, NiO, SnxOy, GaxOy, InxOy, yttria-stabilized zirconia (YSZ), or GaOxNy.

The stress recovery passivation layer 100 may comprise a first passivation layer 110 deposited using at least one of DC plasma, pulsed DC plasma, RF plasma, LF plasma, DC-RF plasma, ICP plasma, ion beam, ion beam irradiation, or electron beam irradiation, with a high energy ranging from 50 W to 3000 W.

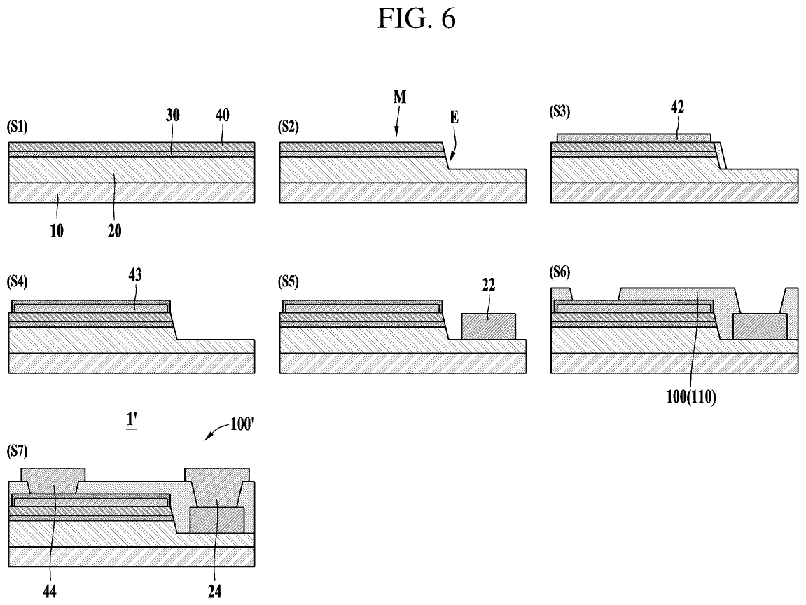

FIG. 6 is a process diagram illustrating a method for manufacturing a micro-LED that compensates for stress relaxation in the mesa region according to the first embodiment of the present invention.

As shown in FIG. 6, the micro-LED manufacturing method may include: Step (S1): Sequentially growing a first semiconductor layer 20, an active layer 30, and a second semiconductor layer 40 on the upper surface of a substrate 10, Step (S2): Forming a mesa structure (M) through etching, Step (S3): Forming the second ohmic electrode layer 42, Step (S4): Forming a reflective electrode layer, Step (S5): Forming the first ohmic electrode layer, Step (S6): Applying a mask with patterns for the first electrode pad and the second electrode pad to form a stress recovery passivation layer (100, 110) on the upper surface and sidewalls of the mesa structure (M) and on the exposed upper surface of the first semiconductor layer 20, and Step (S7): Forming the first bonding electrode layer 24 and the second bonding electrode layer 44.

In Step (S6), forming the stress recovery passivation layer 100, 110 may include depositing the first passivation layer 110 using high-energy particles. At this time, the high-energy particles may resolve lattice defects in the mesa etching region (E) on the sidewalls of the mesa structure and recover stress relaxation in the active layer (MQWs) 30. The high-energy particles may be generated by at least one of DC plasma, pulsed DC plasma, RF plasma, LF plasma, DC-RF plasma, ICP plasma, ion beam irradiation, or electron beam irradiation, with a high energy ranging from 50 W to 3000 W.

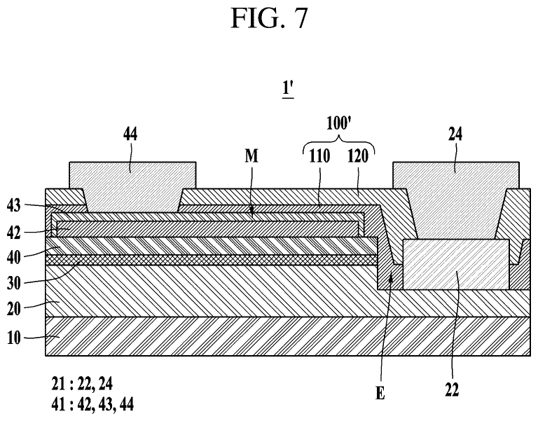

FIG. 7 is a partial cross-sectional view of the micro-LED 1′ according to the second embodiment of the present invention.

As shown in FIG. 7, the micro-LED 1′ of the second embodiment may comprise: a substrate 10, a first semiconductor layer 20, a first electrode pad 21 formed on the first semiconductor layer 20, an active layer 30, a second semiconductor layer 40, a second electrode pad 41 formed on the second semiconductor layer 40, a mesa structure (M), and a stress recovery passivation layer 100′ deposited on the upper surface of the first semiconductor layer 20 exposed by mesa etching.

The substrate 10, first semiconductor layer 20, first electrode pad 21 formed on the first semiconductor layer 20, active layer 30, second semiconductor layer 40, second electrode pad 41 formed on the second semiconductor layer 40, and the mesa structure (M) of the micro-LED 1′ in the second embodiment are identical to those of the micro-LED 1 in the first embodiment. Therefore, detailed descriptions of these components are omitted.

The stress recovery passivation layer 100′ may include: A first passivation layer deposited by particles with high energy ranging from 50 W to 3000 W on the mesa etching region (E) of the upper surface and sidewalls of the mesa structure (M), where the active layer and the second semiconductor layer are laminated, and on the exposed upper surface of the first semiconductor layer, to recover stress relaxation in the active layer caused by etching, and A second passivation layer deposited on the upper surface of the first passivation layer by particles with low energy ranging from 50 W to 3000 W.

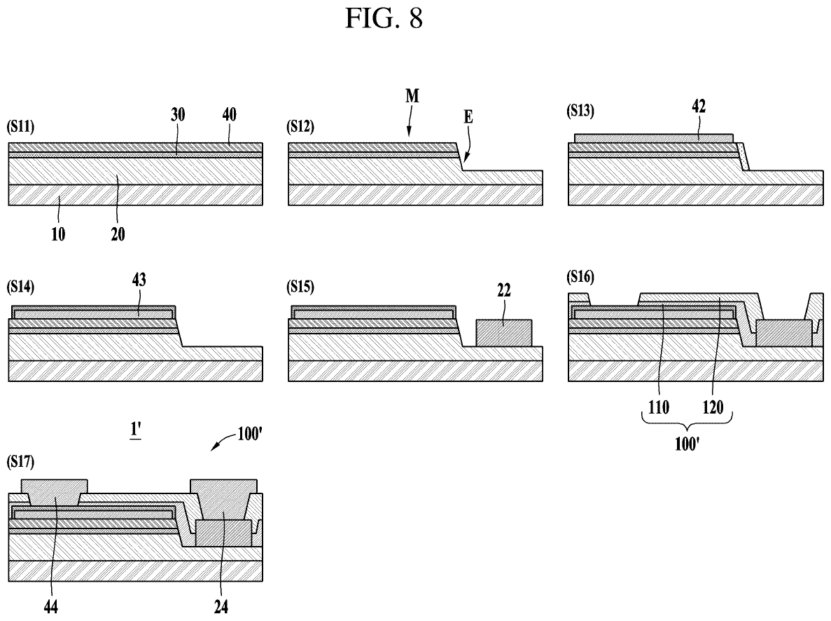

FIG. 8 is a process diagram illustrating a method for manufacturing a micro-LED that compensates for stress relaxation in the mesa region according to the second embodiment of the present invention.

As shown in FIG. 8, the micro-LED manufacturing method of the second embodiment may include: Step (S11): Sequentially growing a first semiconductor layer 20, an active layer 30, and a second semiconductor layer 40 on the upper surface of a substrate 10, Step (S12): Forming a mesa structure including the first semiconductor layer 20, the active layer 30, and the second semiconductor layer 40 through etching, Step (S13): Forming a second ohmic electrode layer 42, Step (S14): Forming a reflective electrode layer, Step (S15): Forming a first ohmic electrode layer, Step (S16): Applying a mask with patterns for the first electrode pad and the second electrode pad to form a stress recovery passivation layer 100′on the upper surface and sidewalls of the mesa structure (M), and on the exposed upper surface of the first semiconductor layer 20, and Step (S17): Forming a first bonding electrode layer 24 and a second bonding electrode layer 44.

In Step (S16), forming the stress recovery passivation layer 100′ may include: Depositing a first passivation layer on the upper surface and sidewalls of the mesa etching region (E) of the mesa structure (M), where the active layer 30 and the second semiconductor layer 40 are laminated, and on the exposed upper surface of the first semiconductor layer 20, by using particles with high energy ranging from 50 W to 3000 W, and Depositing a second passivation layer on the upper surface of the first passivation layer using particles with low energy ranging from 50 W to 3000 W.

In Step (S16), the first passivation layer 110 and the second passivation layer 120 may be formed by at least one of DC plasma, pulsed DC plasma, RF plasma, LF plasma, DC-RF plasma, ICP plasma, ion beam irradiation, or electron beam irradiation.

The second passivation layer 120 may also be formed by a CVD process, such as PECVD, which performs low-energy plasma deposition.

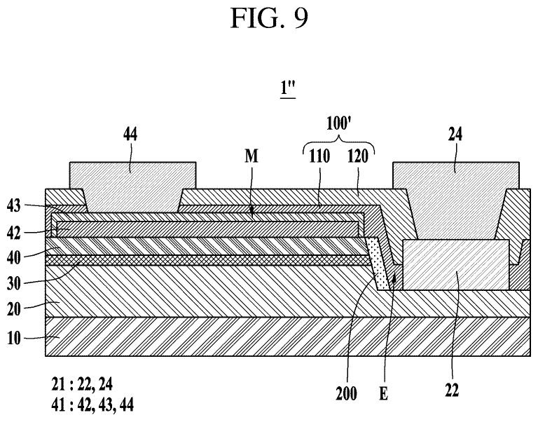

FIG. 9 is a partial cross-sectional view of the micro-LED 1″ according to the third embodiment of the present invention.

As shown in FIG. 9, the micro-LED 1″ of the third embodiment may comprise: a substrate 10, a first semiconductor layer 20, a first electrode pad 21 formed on the first semiconductor layer 20, an active layer 30, a second semiconductor layer 40, a second electrode pad 41 formed on the second semiconductor layer 40, a third passivation layer 200 deposited on the sidewalls of the mesa structure (M), and a stress recovery passivation layer 100′ deposited on the upper surface and sidewalls of the mesa etching region (E) of the mesa structure (M), as well as on the upper surface of the first semiconductor layer 20 exposed by dry etching during mesa etching or ISO processes.

The substrate 10, first semiconductor layer 20, first electrode pad 21 formed on the first semiconductor layer 20, active layer 30, second semiconductor layer 40, second electrode pad 41 formed on the second semiconductor layer 40, mesa structure (M), and stress recovery passivation layer 100′ of the micro-LED 1″ in the third embodiment are identical to those of the micro-LED 1′in the second embodiment. Therefore, detailed descriptions of these components are omitted.

The third passivation layer 200 may be deposited on the mesa etching region (E) on the sidewalls of the mesa structure (M) by particles with high energy ranging from 50 W to 3000 W, in order to recover stress relaxation in the active layer 30 caused by etching.

The insulating material forming the third passivation layer 200 may include at least one of SiO₂, SixNy, SiOxNy, AlN, AlxOy, ZnO, MgO, NiO, SnxOy, GaxOy, InxOy, yttria-stabilized zirconia (YSZ), or GaOxNy.

The third passivation layer 200 may be composed of an insulating film deposited by at least one of DC plasma, pulsed DC plasma, RF plasma, LF plasma, DC-RF plasma, ICP plasma, ion beam irradiation, or electron beam irradiation, with high energy ranging from 50 W to 3000 W.

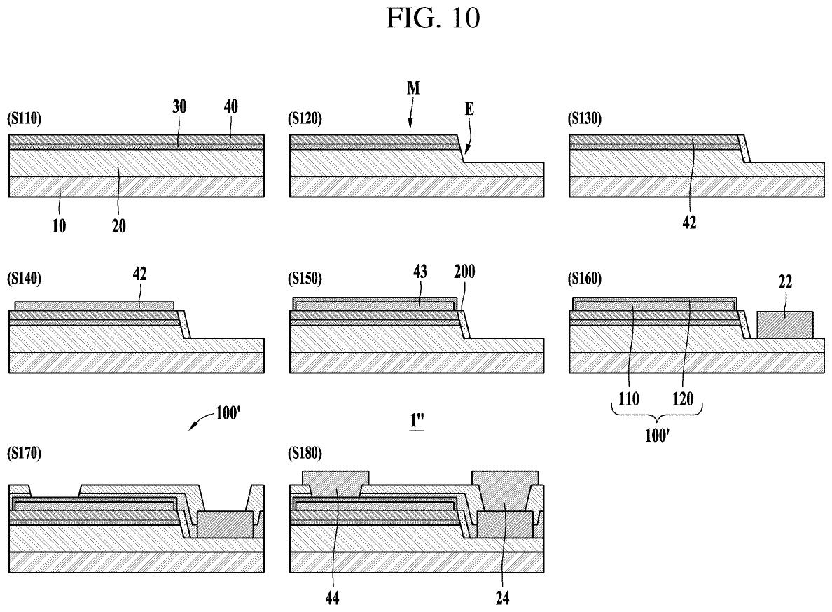

FIG. 10 is a process diagram illustrating a method for manufacturing a micro-LED that compensates for stress relaxation in the mesa region according to the third embodiment of the present invention.

As shown in FIG. 10, the micro-LED manufacturing method of the third embodiment may include: Step (S110): Sequentially growing a first semiconductor layer 20, an active layer 30, and a second semiconductor layer 40 on the upper surface of a substrate 10, Step (S120): Forming a mesa structure (M) including the first semiconductor layer 20, the active layer 30, and the second semiconductor layer 40 through etching, Step (S130): Forming a second ohmic electrode layer 42, Step (S140): Forming a reflective electrode layer, Step (S150): Forming a first ohmic electrode layer, Step (S160): Forming a third passivation layer 200 on the mesa etching region (E) on the sidewalls of the mesa structure (M), Step (S170): Applying a mask with patterns for the first electrode pad 21 and the second electrode pad 41 to form a stress recovery passivation layer 100′on the upper surface and sidewalls of the mesa structure (M) and on the exposed upper surface of the first semiconductor layer 20, and Step (S180): Forming a first bonding electrode layer 24 and a second bonding electrode layer 44.

Forming the third passivation layer 200 may involve depositing the third passivation layer 200 on the mesa etching region (E) on the sidewalls of the mesa structure (M) using particles with high energy ranging from 50 W to 3000 W, to recover stress relaxation in the active layer 30 caused by etching.

Step (S170): Forming the stress recovery passivation layer 100′ may involve: Depositing a first passivation layer on the third passivation layer 200 on the upper surface and sidewalls of the mesa structure (M), where the active layer 30 and the second semiconductor layer 40 are laminated, and on the exposed upper surface of the first semiconductor layer 20, using particles with high energy ranging from 50 W to 3000 W, and Depositing a second passivation layer on the upper surface of the first passivation layer using particles with low energy ranging from 50 W to 3000 W.

In Step (S170): Forming the stress recovery passivation layer 100′, the first passivation layer 110 and the second passivation layer 120 may be formed using one of sputtering with DC plasma, RF plasma, or DC-RF plasma, ion beam implantation, or electron beam irradiation.

The second passivation layer 120 may also be formed using a CVD process, such as PECVD, which performs low-energy plasma deposition.

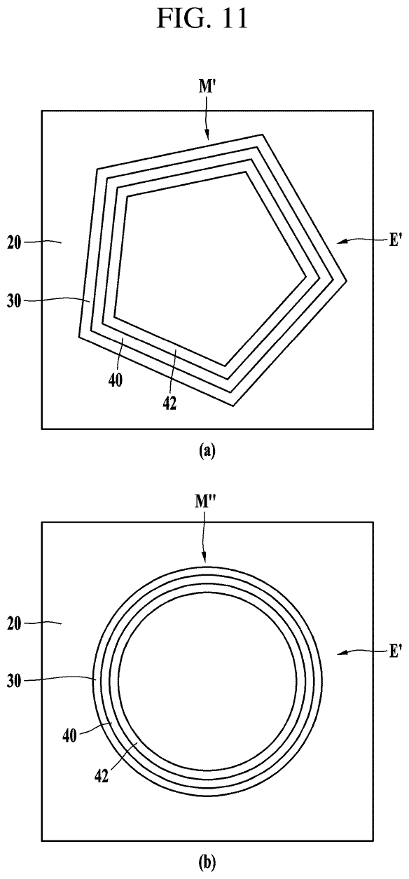

FIG. 11 is a plan view of the stress relaxation-preventing mesa structure according to an embodiment of the present invention.

In the first to third embodiments of the micro-LEDs 1, 1′, 1″, significant stress relaxation tends to occur at the corners of the rectangular mesa structure (M) during dry etching in the mesa etching or ISO processes. Therefore, as shown in FIG. 11, the first to third embodiments of the micro-LEDs 1, 1′, 1″ according to the present invention may be formed to have a polygonal mesa structure (M′) with five or more sides or a circular mesa structure (M″) to minimize stress relaxation at the corners of the mesa structure (M).

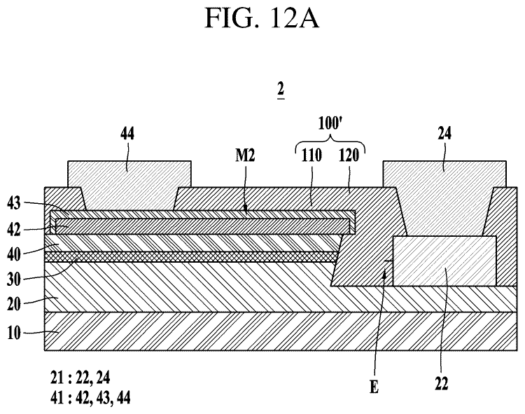

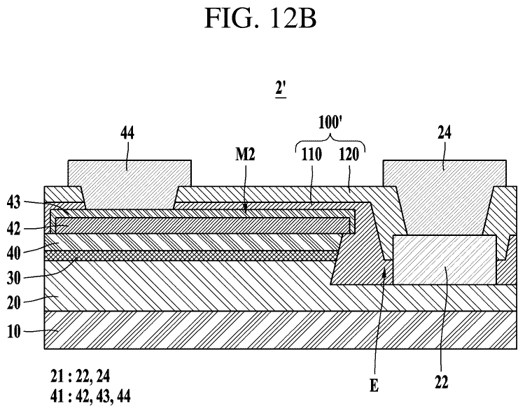

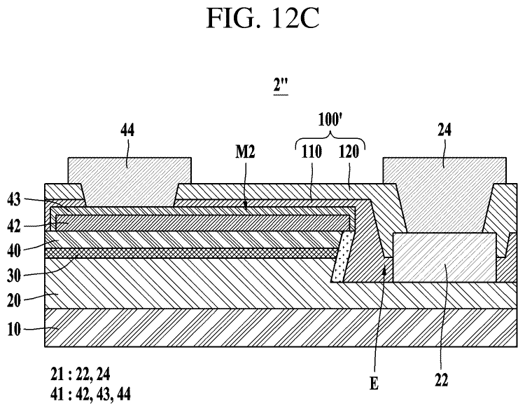

FIGS. 12A to 12C are partial cross-sectional view of a micro-LED having a stress relaxation-preventing inverted mesa structure (M2) according to an embodiment of the present invention.

As shown in FIG. 12A, the micro-LED 2 with the inverted mesa structure (M2) may comprise: a substrate 10, a first semiconductor layer 20, a first electrode pad 21 formed on the first semiconductor layer 20, an active layer 30, a second semiconductor layer 40, a second electrode pad 41 formed on the second semiconductor layer 40, the inverted mesa structure (M2), and a passivation layer deposited on the upper surface of the first semiconductor layer 20 exposed by dry etching during the mesa etching or ISO process.

The inverted mesa structure (M2) may be formed with sidewalls inclined downward at an angle of 80 to 130 degrees relative to the upper surface of the inverted mesa structure (M2). If the inclination angle exceeds 90 degrees, the sidewalls of the inverted mesa structure (M2) may form a reverse slope recessed into the lower portion of the inverted mesa structure (M2). The slope of the inverted mesa structure (M2) may be formed by conducting the dry etching during the mesa etching or ISO process as isotropic etching.

The passivation layer may be a stress recovery passivation layer, such as the stress recovery passivation layer 100. This stress recovery passivation layer 100 may be formed with the same structure and method as the stress recovery passivation layer 100 of the first micro-LED 1.

As shown in FIG. 12B, the micro-LED 2′ with an inverted mesa structure (M2) may comprise: a substrate 10, a first semiconductor layer 20, a first electrode pad 21 formed on the first semiconductor layer 20, an active layer 30, a second semiconductor layer 40, a second electrode pad 41 formed on the second semiconductor layer 40, the inverted mesa structure (M2), and a passivation layer deposited on the upper surface of the first semiconductor layer 20 exposed by dry etching during the mesa etching or ISO process.

The inverted mesa structure (M2) may be formed such that its sidewalls are inclined downward at an angle of 80 to 130 degrees relative to its upper surface. If the inclination angle exceeds 90 degrees, the sidewalls of the inverted mesa structure (M2) may form a reverse slope recessed into the lower portion of the inverted mesa structure (M2).

The slope of the inverted mesa structure (M2) may be formed by conducting the dry etching during the mesa etching or ISO process as isotropic etching.

The passivation layer may be a stress recovery passivation layer. The stress recovery passivation layer may be the stress recovery passivation layer 100′. The stress recovery passivation layer 100′ may be formed with the same structure and method as the stress recovery passivation layer 100′ of the second micro-LED 1′ and the third micro-LED 1″.

As shown in FIG. 12C, the micro-LED 2″ with an inverted mesa structure (M2) may comprise: a substrate 10, a first semiconductor layer 20, a first electrode pad 21 formed on the first semiconductor layer 20, an active layer 30, a second semiconductor layer 40, a second electrode pad 41 formed on the second semiconductor layer 40, the inverted mesa structure (M2), a third passivation layer 200 deposited on the sidewalls of the inverted mesa structure (M2), and a passivation layer deposited on the upper surface of the first semiconductor layer 20 exposed by dry etching during the mesa etching or ISO process.

The inverted mesa structure (M2) may be formed such that its sidewalls are inclined downward at an angle of 80 to 130 degrees relative to its upper surface. If the inclination angle exceeds 90 degrees, the sidewalls of the inverted mesa structure (M2) may form a reverse slope recessed into the lower portion of the inverted mesa structure (M2).

The slope of the inverted mesa structure (M2) may be formed by conducting the dry etching during the mesa etching or ISO process as isotropic etching.

The passivation layer may be a stress recovery passivation layer. The stress recovery passivation layer may be the stress recovery passivation layer 100′. The stress recovery passivation layer 100′ may be formed with the same structure and method as the stress recovery passivation layer 100′ of the second micro-LED 1′ and the third micro-LED 1″.

The third passivation layer 200 may be formed with the same structure and method as the third passivation layer 200 of the third micro-LED 1″.

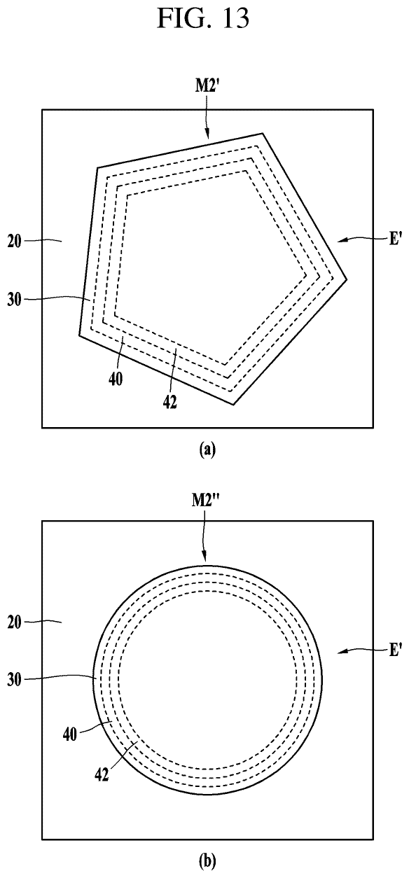

FIG. 13 is a plan view of the stress relaxation-preventing inverted mesa structure according to an embodiment of the present invention.

As shown in FIG. 13, the micro-LEDs 2, 2′, 2″ with an inverted mesa structure (M2) in this embodiment may experience significant stress relaxation at the corners of the rectangular inverted mesa structure (M2) during dry etching in the mesa etching or ISO processes.

Therefore, to minimize stress relaxation at the corners of the inverted mesa structure (M2), the micro-LEDs 2, 2′, 2″ with an inverted mesa structure in this embodiment may be formed with a polygonal inverted mesa structure (M2′) with five or more sides or a circular inverted mesa structure (M2″), as shown in FIG. 13.

### Experimental Example

The characteristics were evaluated after manufacturing the first to third micro-LEDs 1, 1′, 1″ and the inverted mesa structure micro-LEDs 2, 2′, 2″ according to the embodiments of the present invention.

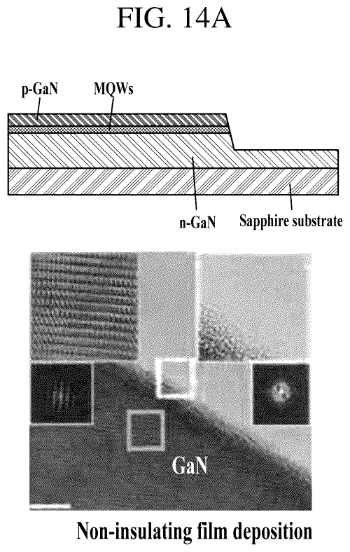

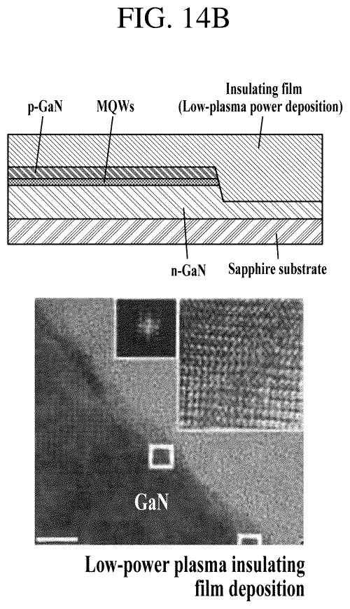

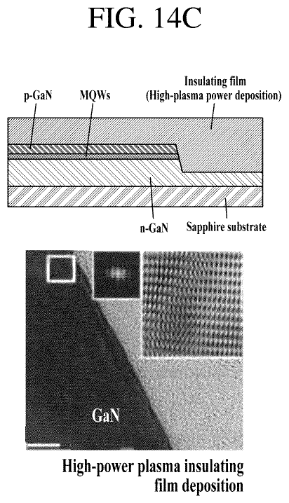

FIGS. 14A to 14C are a partial cross-sectional view and TEM image of the micro-LED before and after passivation layer deposition following mesa etching.

As shown in FIG. 14A, it was confirmed that when the passivation layer (100, 100′, 200) was not applied to the mesa structure or inverted mesa structure (M, M′, M″, M2, M2′, M2″) of the micro-LEDs ( 1, 1′, 1″, 2, 2′, 2″) (Non-passivation layer deposition), stress relaxation and damage to the crystalline structure inside the mesa structure were not recovered.

Additionally, As shown in FIG. 14B, it was confirmed that when a SiO2 insulating film was deposited as a passivation layer (100, 100′) using PECVD equipment with 50 W low-energy plasma (Low-power plasma insulation deposition method), stress relaxation and damage to the crystalline structure inside the mesa structure were also not recovered.

In contrast, As shown in FIG. 14C, when a SiO₂ insulating film was deposited using sputtering with 250 W high-energy plasma according to the embodiment of the present invention (High-power plasma insulation deposition method), it was confirmed that stress relaxation and damage to the crystalline structure were effectively recovered.

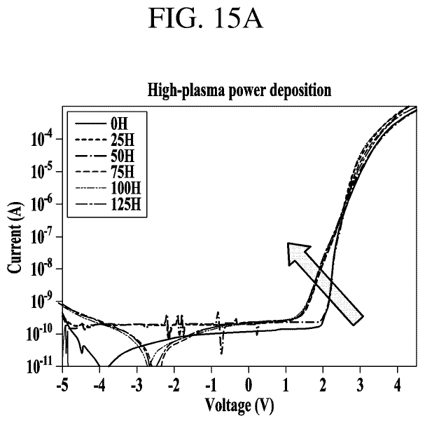

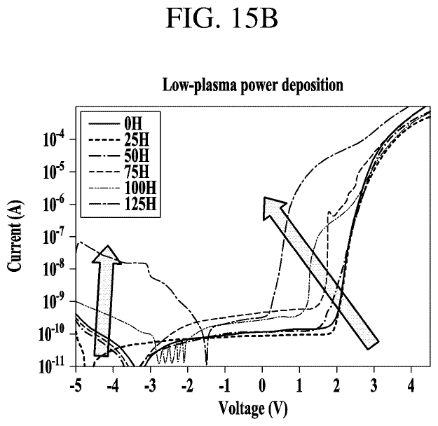

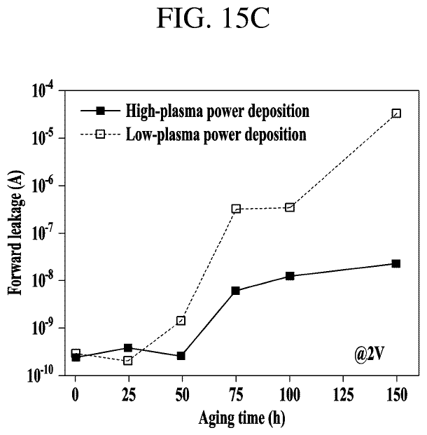

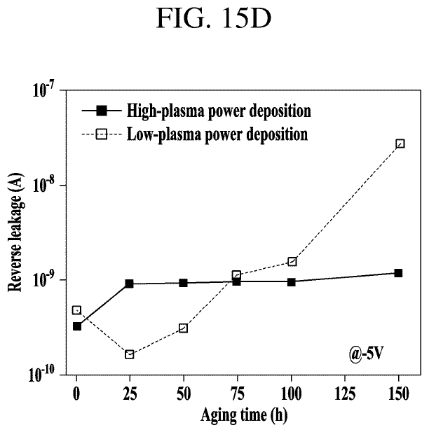

FIGS. 15A to 15D are a graph illustrating the electrical characteristics of a micro-LED fabricated using the high-energy plasma deposition method.

As shown in FIGS. 15A to 15D, at 0 hours, similar reverse and forward leakage currents were observed in both high plasma and low plasma insulation deposition cases. However, at 150 hours, an increase in reverse and forward leakage currents was observed in the case of low plasma insulation deposition.

FIG. 15A is a graph illustrating the I-V (current-voltage) characteristics of a micro-LED. The X-axis represents voltage (V), while the Y-axis represents current (A). Leakage current is observed in the low-voltage region, and a sharp increase in current occurs after a certain threshold voltage. A micro-LED fabricated using the high-energy plasma deposition method is expected to exhibit lower leakage current and a more stable turn-on voltage compared to conventional processes.

FIG. 15B is a graph analyzing the long-term variation in leakage current characteristics. The X-axis represents time (hours), while the Y-axis represents leakage current (A), showing the results of reliability tests conducted in high-temperature or high-humidity environments. The sample fabricated using the high-energy plasma process shows a lower increase in leakage current over time compared to conventional processes. This suggests that the stress-relief passivation layer effectively recovers the crystal structure damage caused by etching.

FIG. 15C shows the variation in current under forward and reverse bias conditions for the micro-LED. Under forward bias, a low turn-on voltage and a high current flow are desirable, while under reverse bias, minimizing leakage current is crucial. A micro-LED fabricated using the high-energy plasma deposition process is expected to exhibit lower reverse bias leakage current and superior conduction characteristics in forward bias conditions.

FIG. 15D is a graph analyzing the degradation of current-voltage characteristics. This graph compares the performance degradation of LEDs when operated for an extended period in high-temperature environments. Over time, conventional processes may experience an increase in voltage accompanied by a decrease in current (efficiency degradation). In contrast, LEDs fabricated using the high-energy plasma deposition process exhibit minimal electrical characteristic changes and maintain stable performance.

In conclusion, the graphs in FIGS. 15A to 15D demonstrate that micro-LEDs fabricated using the high-energy plasma deposition process have higher electrical reliability, reduced leakage current, and enhanced long-term stability compared to those produced using conventional methods.

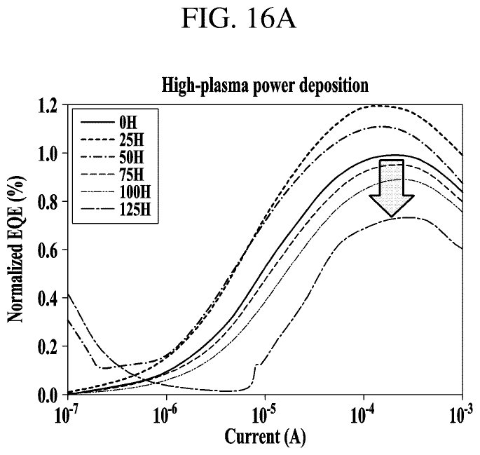

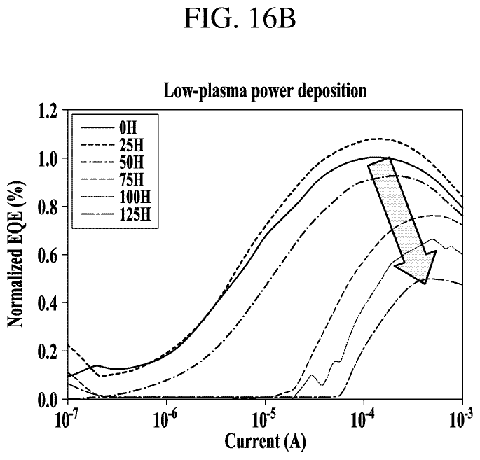

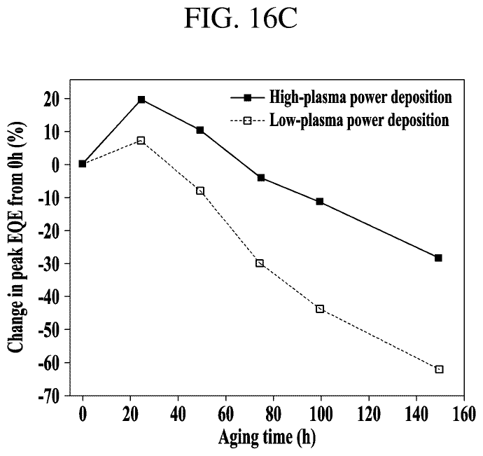

FIGS. 16A to 16C are a graph illustrating the external quantum efficiency (EQE) characteristics of a micro-LED fabricated using the high-energy plasma deposition method.

After fabricating the micro-LEDs with high plasma and low plasma insulation deposition, the reliability of EQE characteristic changes over time at 125° C. was evaluated.

As shown in FIGS. 16A to 16C, it was confirmed that the EQE of the micro-LED fabricated with low plasma insulation deposition significantly decreased compared to that of the micro-LED fabricated with high plasma insulation deposition.

FIG. 16A presents the EQE as a function of current density for micro-LEDs. The X-axis represents the current density (A/cm²), while the Y-axis represents the external quantum efficiency (%). The graph compares the performance of micro-LEDs fabricated using high-energy plasma deposition with those produced using conventional methods. The micro-LEDs manufactured with the high-energy plasma deposition method exhibit a higher peak EQE and improved efficiency roll-off characteristics at higher current densities, indicating reduced non-radiative recombination losses.

FIG. 16B illustrates the EQE degradation over time under high-temperature operating conditions. The X-axis represents the operating time (hours), while the Y-axis represents the normalized EQE (%). The data demonstrate that micro-LEDs fabricated using the high-energy plasma deposition method maintain a more stable EQE over prolonged operation compared to conventional devices. This suggests that the passivation layer applied via high-energy plasma deposition effectively mitigates defect formation and reduces efficiency degradation over time.

FIG. 16C compares the EQE characteristics of micro-LEDs with different passivation techniques. The X-axis represents the current density (A/cm²), and the Y-axis represents EQE (%). The graph shows that the micro-LEDs with high-energy plasma-deposited passivation layers outperform those with conventional passivation methods, exhibiting higher initial EQE values and slower efficiency roll-off. This result indicates that high-energy plasma deposition enhances carrier injection efficiency and reduces surface defect-related recombination.

These graphs collectively demonstrate that the high-energy plasma deposition method significantly improves the external quantum efficiency, stability, and long-term reliability of micro-LEDs compared to conventional fabrication techniques.

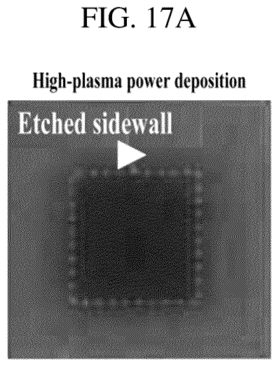

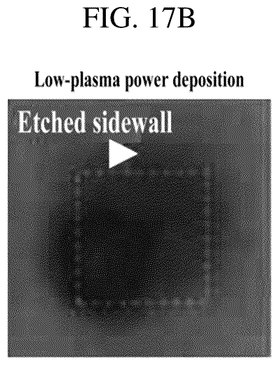

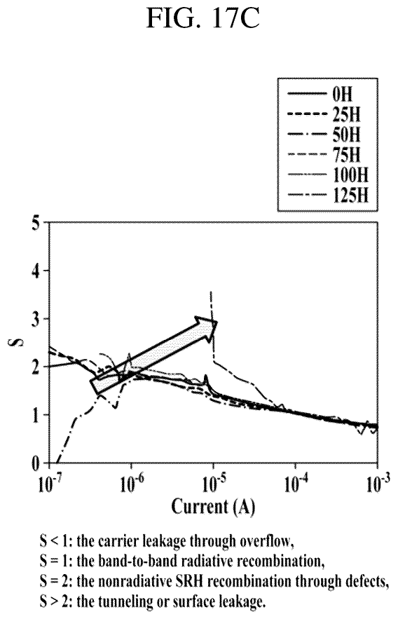

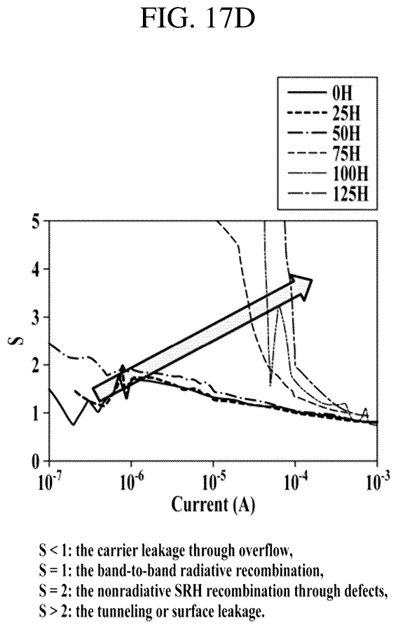

FIGS. 17A to 17D are a graph illustrating the external quantum efficiency (EQE) characteristics of micro-LEDs fabricated with high plasma and low plasma insulation deposition.

As shown in FIGS. 17A to 17D, the cause of the degradation in electrical characteristics and EQE was identified through the emission pattern. Abnormal emission due to stress relaxation and defects in the crystalline structure was observed on the sidewalls of the mesa structure in the micro-LED fabricated with low plasma insulation deposition. Additionally, it was confirmed that the S-parameter characteristics gradually increased.

FIG. 17A shows an emission pattern of a micro-LED fabricated using high plasma power deposition. The image highlights the etched sidewall, indicating that the passivation layer effectively reduces damage at the mesa structure. The uniform brightness suggests improved electrical characteristics and reduced leakage current.

FIG. 17B presents the emission pattern of a micro-LED fabricated using low plasma power deposition. Compared to FIG. 17A, the image shows more pronounced dark regions around the etched sidewall, indicating increased defect density and higher leakage current due to insufficient passivation.

FIG. 17C is a graph illustrating the S-parameter variation over time for a micro-LED fabricated using high plasma power deposition. The X-axis represents current (A), while the Y-axis represents the S-parameter. The stability of the curves over 125 hours suggests minimal degradation in electrical performance, demonstrating that the high-energy plasma deposition effectively enhances long-term reliability.

FIG. 17D is a graph showing the S-parameter variation for a micro-LED fabricated using low plasma power deposition. Compared to FIG. 17C, the curves show a more significant shift over time, indicating increased degradation and higher leakage current. This suggests that low plasma power deposition results in weaker passivation and reduced device reliability.

These figures collectively demonstrate that high plasma power deposition significantly improves the external quantum efficiency, electrical stability, and long-term performance of micro-LEDs compared to low plasma power deposition.

Although the embodiments have been described above with reference to limited drawings, it will be apparent to those skilled in the art that various modifications and variations may be made based on the above description. For example, the described technologies may be performed in an order different from the described method, and/or the components of the described systems, structures, devices, circuits, etc., may be combined or arranged in a manner different from the described method, or may be replaced or substituted with other components or equivalents, while still achieving appropriate results.

Therefore, other implementations, other embodiments, and equivalents to the claims described below are within the scope of the following claims.

What is claimed is:

1. A micro-LED comprising:
a substrate;
a first semiconductor layer laminated on an upper surface of the substrate;
a first electrode pad formed on an upper surface of the first semiconductor layer;
an active layer laminated on an upper surface of the first semiconductor layer;
a second semiconductor layer laminated on an upper surface of the active layer;
a second electrode pad formed on the second semiconductor layer; and
a stress recovery passivation layer configured to recover stress relaxation caused in the active layer by etching,
wherein the stress recovery passivation layer comprises a first passivation layer deposited by particles having a first energy on a portion of an upper surface and sidewalls of a mesa structure during the etching of the second semiconductor layer.

2. The micro-LED of claim 1,
wherein the stress recovery passivation layer comprises
at least one of SiO₂, SixNy, SiOxNy, AlN, AlxOy, ZnO, MgO, NiO, SnxOy, GaxOy, InxOy, yttria-stabilized zirconia (YSZ), and GaOxNy.

3. The micro-LED of claim 1,
wherein the particles having the first energy are particles with an energy of 50 W to 3000 W, generated by at least one of DC plasma, pulsed DC plasma, RF plasma, LF plasma, DC-RF plasma, ion beam irradiation, and electron beam irradiation.

4. The micro-LED of claim 1,
wherein the stress recovery passivation layer further comprises a second passivation layer deposited on an upper surface of the first passivation layer by particles having a second energy.

5. The micro-LED of claim 4,
wherein the particles having the second energy are particles with an energy of 50 W to 3000 W, generated by at least one of DC plasma, pulsed DC plasma, RF plasma, LF plasma, DC-RF plasma, ion beam irradiation, and electron beam irradiation.

6. The micro-LED of claim 1,
wherein the stress recovery passivation layer further comprises a third passivation layer deposited by particles having the first energy on sidewalls of the mesa structure beneath the first passivation layer, the third passivation layer being configured to recover stress relaxation of the active layer caused by etching.

7. A micro-LED comprising:
a substrate;
a first semiconductor layer laminated on an upper surface of the substrate;
a first electrode pad formed on an upper surface of the first semiconductor layer;
an active layer laminated on an upper surface of the first semiconductor layer;
a second semiconductor layer laminated on an upper surface of the active layer;
a second electrode pad formed on the second semiconductor layer; and
a mesa structure comprising the active layer and the second semiconductor layer laminated together, formed by etching the second semiconductor layer;
wherein the mesa structure has a shape of at least a polygon with five or more sides or a circular shape.

8. A micro-LED comprising:
a substrate;
a first semiconductor layer laminated on an upper surface of the substrate;
a first electrode pad formed on an upper surface of the first semiconductor layer;
an active layer laminated on an upper surface of the first semiconductor layer;
a second semiconductor layer laminated on an upper surface of the active layer;
a second electrode pad formed on the second semiconductor layer; and
a passivation layer formed on a portion of the upper surface and sidewalls of an inverted mesa structure, where the active layer and the second semiconductor layer are laminated, and on a portion of the exposed upper surface of the first semiconductor layer, the inverted mesa structure being formed by etching the second semiconductor layer;
wherein the sidewalls of the inverted mesa structure are configured to have a downward slope of 80 degrees to 130 degrees relative to its upper surface.

9. A method for manufacturing a micro-LED, comprising:
growing a first semiconductor layer, an active layer, and a second semiconductor layer sequentially on an upper surface of a substrate;
forming a mesa structure including the first semiconductor layer, the active layer, and the second semiconductor layer by etching; and
forming a stress recovery passivation layer on a portion of the upper surface and sidewalls of the mesa structure, and on the exposed portion of the upper surface of the first semiconductor layer by applying a mask with patterns for a first electrode pad and a second electrode pad,
wherein forming the stress recovery passivation layer comprises depositing a first passivation layer on a portion of the upper surface and sidewalls of the mesa structure by using particles having a first energy to recover stress relaxation of the active layer caused by etching.

10. The method for manufacturing a micro-LED of claim 9,
wherein the particles having the first energy used in forming the stress recovery passivation layer are particles with an energy of 50 W to 3000 W, generated by at least one of DC plasma, pulsed DC plasma, RF plasma, LF plasma, DC-RF plasma, ion beam irradiation, and electron beam irradiation.

11. The method for manufacturing a micro-LED of claim 9,
wherein forming the stress recovery passivation layer further comprises forming a second passivation layer on the upper surface of the first passivation layer by using particles having an energy of 50 W to 3000 W after depositing the first passivation layer.

12. The method for manufacturing a micro-LED of claim 9,
wherein forming the stress recovery passivation layer further comprises, before forming the first passivation layer, depositing a third passivation layer on the sidewalls of the mesa structure by using particles having the first energy to recover stress relaxation of the active layer caused by etching.
